(19) United States
(12) Patent Application Publication
(10) Pub. No.: US 2025/0221243 A1
(43) Pub. Date: Jul. 3, 2025

(54) LIGHT EMITTING ELEMENT AND DISPLAY DEVICE INCLUDING THE SAME

(71) Applicant: Samsung Display Co., Ltd., Yongin-si (KR)

(72) Inventors: HWI KIM, Yongin-si (KR); JUNGSUN PARK, Yongin-si (KR); JI-HEE SON, Yongin-si (KR); SEOULKI LEE, Yongin-si (KR); SEUNGJUN LEE, Yongin-si (KR); AREUM LEE, Yongin-si (KR); YEONHWA LEE, Yongin-si (KR); JOONGU LEE, Yongin-si (KR)

(73) Assignee: Samsung Display Co., Ltd., Yongin-si (KR)

(21) Appl. No.: 19/000,097

(22) Filed: Dec. 23, 2024

(30) Foreign Application Priority Data
Jan. 2, 2024 (KR) 10-2024-0000335

(51) Int. Cl. H10K 59/80

(52) U.S. Cl. CPC H10K 59/80524

(57) ABSTRACT

A light emitting element includes a first electrode, a light emitting structure disposed on the first electrode and including an emission layer, a second electrode disposed on the light emitting structure and including silver (Ag) and a metal dopant, and a capping layer directly disposed on the second electrode. An average volume ratio of the metal dopant in the second electrode is less than or equal to about 30%, and a volume ratio of the metal dopant in a region adjacent to the capping layer is less than the average volume ratio of the metal dopant in the second electrode, and thus both maintaining excellent electrical and optical properties and having improved reliability.

### CROSS-REFERENCE TO RELATED APPLICATION(S)

This application claims priority to and benefits of Korean Patent Application No. 10-2024-0000335 under 35 U.S.C. § 119, filed on Jan. 2, 2024, in the Korean Intellectual Property Office (KIPO), the entire contents of which are incorporated herein by reference.

### BACKGROUND

### 1. Technical Field

The disclosure herein relates to a light emitting element including an electrode having an optimized ratio of a metal dopant, and a display device including the same.

### 2. Description of Related Art

Various types of display devices used for multimedia devices such as television sets, mobile phones, tablet computers, navigation systems, and game consoles are being developed. In the display devices, a so-called self-luminescent display element is used which accomplishes display by causing a light emitting material containing organic compounds or quantum dots in an emission layer disposed between electrodes facing each other to emit light.

As for light emitting elements and application of the light emitting elements to the display devices, there is a demand for elements having excellent electrical and optical properties and maintaining reliability despite prolonged exposure to external light.

### SUMMARY

The disclosure provides a light emitting element having improved reliability.

The disclosure also provides a display device having improved reliability and display quality.

According to an embodiment of the disclosure, a light emitting element may include a first electrode, a light emitting structure disposed on the first electrode and including an emission layer, a second electrode disposed on the light emitting structure and including silver (Ag) and a metal dopant, and a capping layer directly disposed on the second electrode. An average volume ratio of the metal dopant in the second electrode may be less than or equal to about 30%, and a volume ratio of the metal dopant in a region adjacent to the capping layer may be less than the average volume ratio of the metal dopant in the second electrode.

In an embodiment, the metal dopant may include at least one of Al, Au, Cu, Mg, Ti, In, Ni, C, Pd, F, Na, Si, Ca, Mn, Fe, Co, Zn, Ga, Ge, Mo, Sn, In, Pt, Pb, Fe, Yb, Lu, or Pa.

In an embodiment, the metal dopant may be Mg, and the average volume ratio of the metal dopant in the second electrode may be in a range of about 3% to about 10%.

In an embodiment, the volume ratio of the metal dopant in the second electrode may gradually decrease in a direction from the light emitting structure to the capping layer.

In an embodiment, the second electrode may have a thickness in a range of about 50 Å to about 300 Å.

In an embodiment, the second electrode may be formed by co-deposition of the silver and the metal dopant using a method of thermal evaporation.

In an embodiment, the second electrode may include a first region including a first surface contacting the capping layer, a second region including a second surface contacting the light emitting structure, and a third region disposed between the first region and the second region, and a first volume ratio of the metal dopant in the first region and a second volume ratio of the metal dopant in the second region may each be less than the average volume ratio of the metal dopant in the second electrode.

In an embodiment, a third volume ratio of the metal dopant in the third region may be greater than the average volume ratio of the metal dopant in the second electrode.

In an embodiment, the third region may include a first sub-region having a third volume ratio of the metal dopant less than the average volume ratio of the metal dopant in the second electrode, a second sub-region disposed between the first region and the first sub-region and having a fourth volume ratio of the metal dopant greater than the average volume ratio of the metal dopant in the second electrode, and a third sub-region disposed between the second region and the first sub-region and having a fifth volume ratio of the metal dopant greater than the average volume ratio of the metal dopant in the second electrode.

In an embodiment, the third region may include at least one sub-region having a third volume ratio of the metal dopant less than the average volume ratio of the metal dopant in the second electrode.

In an embodiment, the first electrode may be a reflective electrode, and the second electrode may be a transmissive electrode or a transflective electrode.

In an embodiment, the second electrode may have a transmittance greater than or equal to about 70% at about 550 nm.

In an embodiment, the light emitting structure may include the emission layer, a hole transport region disposed between the first electrode and the emission layer, and an electron transport region disposed between the emission layer and the second electrode, and the electron transport region may be directly disposed below the second electrode and may include an electron injection layer including Yb.

In an embodiment of the disclosure, a display device may include a circuit layer, and a display element layer disposed on the circuit layer and including a light emitting element and a pixel defining layer including a pixel opening. The light emitting element may include a first electrode, a light emitting structure disposed on the first electrode and including an emission layer, a second electrode disposed on the light emitting structure and including silver (Ag) and a metal dopant, and a capping layer directly disposed on the second electrode. An average volume ratio of the metal dopant in the second electrode may be less than or equal to about 30%, and a volume ratio of the metal dopant in a region adjacent to the capping layer is less than the average volume ratio of the metal dopant in the second electrode.

In an embodiment, the metal dopant may include at least one of Al, Au, Cu, Mg, Ti, In, Ni, C, Pd, F, Na, Si, Ca, Mn, Fe, Co, Zn, Ga, Ge, Mo, Sn, In, Pt, Pb, Fe, Yb, Lu, or Pa.

In an embodiment, the second electrode may include a first region including a first surface contacting the capping layer, a second region including a second surface contacting the light emitting structure, and a third region disposed between the first region and the second region, and a first volume ratio of the metal dopant in the first region and a second volume ratio of the metal dopant in the second region may each be less than the average volume ratio of the metal dopant in the second electrode.

In an embodiment, a third volume ratio of the metal dopant in the third region may be greater than the average volume ratio of the metal dopant in the second electrode.

In an embodiment, the third region may include a first sub-region having a third volume ratio of the metal dopant less than the average volume ratio of the metal dopant in the second electrode, a second sub-region disposed between the first region and the first sub-region and having a fourth volume ratio of the metal dopant greater than the average volume ratio of the metal dopant in the second electrode, and a third sub-region disposed between the second region and the first sub-region and having a fifth volume ratio of the metal dopant greater than the average volume ratio of the metal dopant in the second electrode.

In an embodiment, the metal dopant may be Mg, and the second electrode may be formed by co-deposition of the silver and the Mg using a method of thermal evaporation.

In an embodiment, the light emitting structure may include the emission layer, a hole transport region disposed between the first electrode and the emission layer, and an electron transport region disposed between the emission layer and the second electrode, and the electron transport region may be directly disposed below the second electrode and include an electron injection layer including Yb.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view of a display device according to an embodiment;

FIG. 2 is a schematic cross-sectional view showing a portion corresponding to line I-I′ of FIG. 1;

FIG. 3 is a plan view showing a display device of an embodiment;

FIG. 4 is a schematic cross-sectional view showing a portion corresponding to line II-II′ of FIG. 3;

FIG. 5 is a schematic cross-sectional view showing a light emitting element of an embodiment;

FIG. 6A is a schematic cross-sectional view enlarging a partial region of a light emitting element of an embodiment;

FIG. 6B is a graph showing a doping concentration profile of a metal dopant in a second electrode in a light emitting element of to an embodiment;

FIG. 7A is a graph showing a doping concentration profile of a metal dopant in a second electrode of Example;

FIG. 7B is a graph showing a doping concentration profile of a metal dopant in a second electrode of Comparative Example;

FIG. 7C is a graph showing the results of evaluating the transmittance of Example and Comparative Example;

FIG. 7D is a graph showing the results of evaluating the reflectance of Example;

FIG. 8 is a schematic cross-sectional view enlarging a partial region of a light emitting element of an embodiment;

FIG. 9A is a graph showing a doping concentration profile of a metal dopant in a second electrode of Example;

FIG. 9B is a graph showing the results of evaluating the transmittance of Example;

FIG. 10 is a schematic cross-sectional view enlarging a partial region of a light emitting element of an embodiment;

FIG. 11A is a graph showing a doping concentration profile of a metal dopant in a second electrode of Example; and

FIG. 11B is a graph showing the results of evaluating the transmittance of Example.

### DETAILED DESCRIPTION OF THE EMBODIMENTS

The disclosure may be modified in many alternate forms, and thus specific embodiments will be illustrated in the drawings and described in detail. It should be understood, however, that it is not intended to limit the disclosure to the particular forms disclosed, but rather, is intended to cover all modifications, equivalents, and alternatives falling within the spirit and scope of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like reference numerals refer to like elements. The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the disclosure. The singular forms are intended to include the plural forms as well, unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, being “directly disposed on” may mean that there is no additional layer, film, region, plate, or the like between a part and another part such as a layer, a film, a region, a plate, or the like. For example, being “directly disposed on” may mean that two layers or two members are disposed without using an additional member such as an adhesive member, therebetween.

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a light emitting element and a display device according to an embodiment of the disclosure will be described with reference to the accompanying drawings.

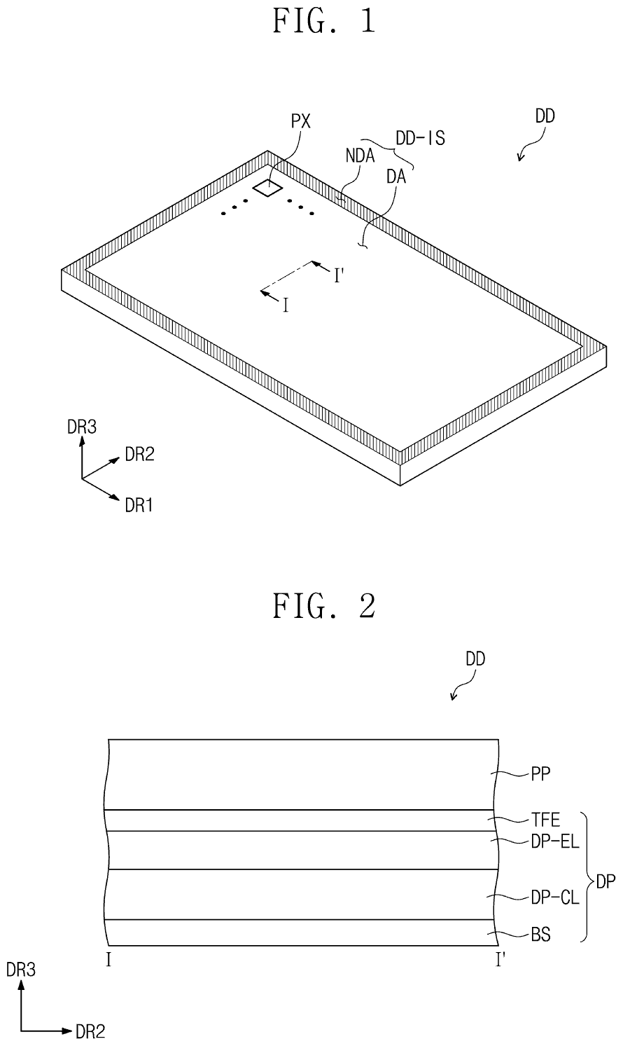

FIG. 1 is a perspective view showing a display device according to an embodiment. A display device DD may be a device activated according to electrical signals. For example, the display device DD may be a large-sized device such as televisions, monitors, or outdoor billboards. For example, the display device DD may be a small- and medium-sized device such as personal computers, laptop computers, personal digital terminals, car navigation systems, game consoles, smart phones, tablets, and cameras. However, the disclosure is not limited thereto, and other electronic devices may be employed as long as not departing from the disclosure.

The display device DD may display images (or videos) through a display surface DD-IS. The display surface DD-IS may be parallel to a plane defined by a first direction DR1 and a second direction DR2 intersecting the first direction DR1. The display surface DD-IS may include a display region DA and a non-display region NDA.

In the display region DA, a pixel PX may be disposed. The non-display region NDA may be a portion in which the pixel PX is not disposed. The non-display region NDA may be defined along an edge of the display surface DD-IS. The non-display region NDA may surround the display region DA in a plan view. However, the disclosure is not limited thereto, and the non-display region NDA may not be provided, or the non-display region NDA may be disposed only on a side of the display region DA.

FIG. 1 shows the display device DD provided with the flat display surface DD-IS, but the disclosure is not limited thereto. The display device DD may include a curved display surface or a three-dimensional display surface. The three-dimensional display surface may include multiple display regions facing different directions.

FIG. 1 and the following drawings show first to third directions DR1 to DR3, and directions indicated by the first to third directions DR1, DR2, and DR3 described herein are relative concepts, and may thus be changed to other directions. In addition, the directions indicated by the first to third directions DR1, DR2, and DR3 may be described as first to third directions, and the same reference numerals may be used. The first direction DR1 and the second direction DR2 may be perpendicular to each other, and a third direction DR3 may be a normal direction to a plane defined by the first direction DR1 and the second directions DR2. In the specification, the term ‘plane’ refers to a plane defined by the first direction DR1 and the second direction DR2, and the term ‘cross-section’ refers to a plane perpendicular to the plane defined by the first direction DR1 and the second directions DR2 and parallel to the third direction DR3. A thickness direction of the display device DD may be parallel to the third direction DR3, which is a normal direction with respect to the plane defined by the first direction DR1 and the second direction DR2.

An upper surface (or a front surface) and a lower surface (or a rear surface) of members constituting the display device DD may be defined with respect to the third direction DR3. For example, among the two surfaces facing in the third direction DR3 in one member, the surface relatively adjacent to the display surface DD-IS may be defined as a front surface (or an upper surface), and the surface relatively spaced apart from the display surface DD-IS may be defined as a rear surface (or a lower surface). In the specification, an upper portion (or an upper side) and a lower portion (or a lower side) may be defined with respect to the third direction DR3, and the upper portion (or upper side) may be defined as a direction closer toward the display surface DD-IS, and the lower portion (or lower side) may be defined as a direction away from the display surface DD-IS.

Herein, when a component is “directly disposed/directly formed” on another component, it indicates that a third component is not disposed between one component and another component. For example, when a component is “directly placed/directly formed” on another component, it indicates that a component is in “contact” with another component.

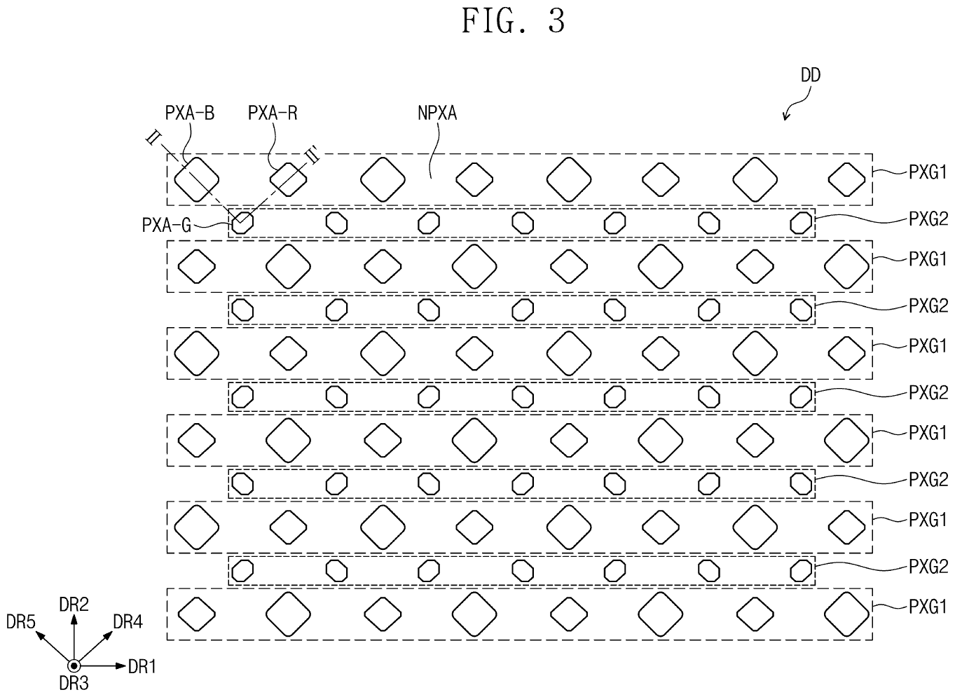

FIG. 2 is a schematic cross-sectional view showing a portion corresponding to line I-I′ of FIG. 1. FIG. 2 may be a schematic cross-sectional view of a display device according to an embodiment.

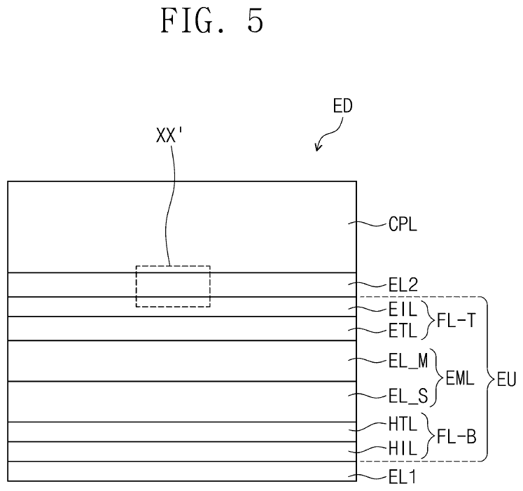

The display device DD may include a display panel DP and an optical structure layer PP disposed on the display panel DP. The display panel DP may include a display element layer DP-EL. The display element layer DP-EL may include a light emitting element ED (FIG. 4). In an embodiment, the display panel DP may also include an encapsulation layer TFE disposed on the display element layer DP-EL. The encapsulation layer TFE may be directly disposed on the display element layer DP-EL or may be bonded to the display element layer DP-EL through a separate member.

The optical structure layer PP may be disposed on the display panel DP to control reflected light in the display panel DP by external light. The optical structure layer PP may be a reflection reduction layer reducing reflectance by external light. For example, the optical structure layer PP may include a polarizing film including a phase retarder and/or a polarizer, multi-layered reflection layers that induces destructive interference of reflected light, or color filters disposed corresponding to the pixel arrangement and light emitting color of the display panel DP. In case that the optical structure layer PP includes color filters, the color filters may be arranged in consideration of the light emitting colors of pixels included in the display panel DP. In another embodiment, the optical structure layer PP may not be provided.

The display panel DP may be configured to substantially generate images. In the display device DD of an embodiment, the display panel DP may be a light emitting display panel. In the display device DD according to an embodiment, the display element layer DP-EL may be a self-luminescent display layer. For example, the display element layer DP-EL may include a micro-LED display layer, a nano LED display layer, an organic light emitting display layer, or a quantum dot light emitting display layer. However, the disclosure is not limited thereto as long as the display element implements a self-luminescent display element layer.

The organic light emitting display layer may include an organic electroluminescence element containing an organic light emitting material. The quantum dot light emitting display layer may include an emission layer containing quantum dots and/or quantum rods. The micro-LED display layer may include a micro light emitting diode element, which is a subminiature light emitting element, and the nano LED display layer may include a nano light emitting diode element. Hereinafter, the display element layer DP-EL is described as an organic light emitting display layer according to an embodiment. However, for components other than the emission layer, the same may be applied to a structure of other display layers other than the organic light emitting display layer.

The display panel DP may include a base substrate BS, a circuit layer DP-CL disposed on the base substrate BS, and a display element layer DP-EL disposed on the circuit layer DP-CL.

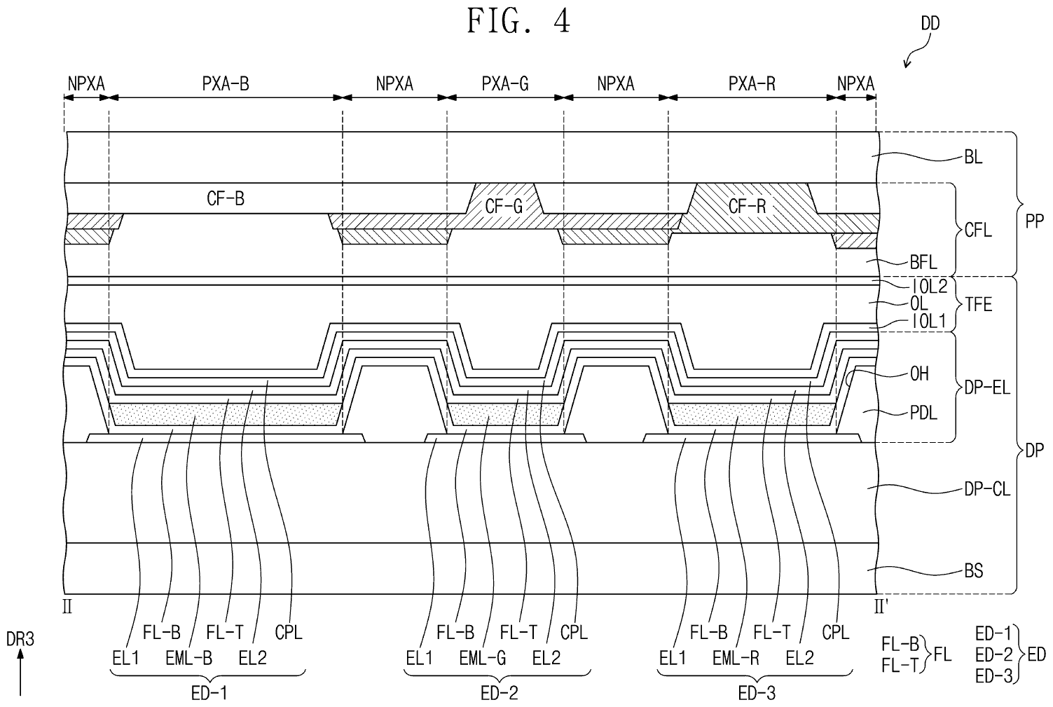

FIG. 3 is a plan view of a display device according to an embodiment. FIG. 4 is a schematic cross-sectional view showing a portion corresponding to line II-II′ of FIG. 3. FIG. 4 may be a schematic cross-sectional view showing a display device of an embodiment.

Referring to FIGS. 3 and 4, the display device DD may include multiple light emitting regions PXA-B, PXA-G, and PXA-R, which are repeatedly arranged throughout the display region DA (FIG. 1). The display device DD of an embodiment may include first to third light emitting region PXA-B, PXA-G, and PXA-R, which are distinct from one another. In an embodiment, the display device DD may include a peripheral region NPXA disposed around the first to third light emitting region PXA-B, PXA-G, and PXA-R. The peripheral region NPXA may set boundaries between the first to third light emitting regions PXA-B, PXA-G, and PXA-B. The peripheral region NPXA may surround the first to third light emitting regions PXA-B, PXA-G, and PXA-B in a plan view. A structure that prevents color mixing between the first to third light emitting regions PXA-B, PXA-G, and PXA-R, for example, a pixel defining layer PDL, may be disposed in the peripheral region NPXA.

The pixel defining layer PDL may define light emitting regions PXA-B, PXA-G, and PXA-R. The light emitting regions PXA-B, PXA-G, and PXA-R, and the peripheral region NPXA may be separated by the pixel defining layer PDL.

The display panel DP according to an embodiment may include multiple light emitting elements ED-1, ED-2, and ED-3, which emit light in different wavelength ranges. The light emitting elements ED-1, ED-2, and ED-3 may emit light of different colors. For example, the display panel DP may include a first light emitting element ED-1 emitting blue light, a second light emitting element ED-2 emitting green light, and a third light emitting element ED-3 emitting red light. However, the disclosure is not limited thereto, and in another embodiment, the first to third light emitting elements ED-1, ED-2 and ED-3 may emit light in a same wavelength range or at least one of the first to third light emitting elements ED-1, ED-2 and ED-3 may emit light in different wavelength ranges.

The light emitting regions PXA-B, PXA-G, and PXA-R may each be a region emitting light generated from each of light emitting elements ED-1, ED-2, and ED-3. FIGS. 3 and 4 show first to third light emitting regions PXA-B, PXA-G, and PXA-R, which emit blue light, green light, and red light, respectively. For example, the display device DD of an embodiment may include a first light emitting region PXA-B emitting blue light, a second light emitting region PXA-G emitting green light, and a third light emitting region PXA-R emitting red light, which are separated.

In the display device DD of an embodiment shown in FIGS. 3 and 4, the light emitting regions PXA-B, PXA-G and PXA-R may have different size of areas according to the color emitted from the emission layers EML-B, EML-G, and EML-R of the light emitting elements ED-1, ED-2 and ED-3. FIG. 3 shows, as an embodiment, the first to third light emitting regions PXA-B, PXA-G, and PXA-R having a same planar shape and having different planar areas in a plan view, but the disclosure is not limited thereto.

The first light emitting region PXA-B corresponding to the first light emitting element ED-1 emitting blue light may have a largest area, and the second light emitting region PXA-G corresponding to the second light emitting element ED-2 emitting green light may have a smallest area. However, the disclosure is not limited thereto, and the first to third light emitting regions PXA-B, PXA-G, and PXA-R may emit light of colors other than blue light, green light, and red light. In another embodiment, the first to third light emitting regions PXA-B, PXA-G, and PXA-R may have a same area, or may be provided with area ratios different from the embodiment shown in FIG. 3. The areas of the first to third light emitting regions PXA-B, PXA-G, and PXA-R may be set according to the color of emitted light. The areas may be areas in a plan view.

The first light emitting region PXA-B and the third light emitting region PXA-R may be alternately arranged in the first direction DR1 to form a first group PXG1. The second light emitting region PXA-G may be arranged in the first direction DR1 to form a second group PXG2. The first group PXG1 may be spaced apart from the second group PXG2 in the second directions DR2. The first group PXG1 and the second group PXG2 may each be provided in plurality. The first groups PXG1 and the second groups PXG2 may be alternately arranged in the second direction DR2.

One third light emitting region PXA-R may be spaced apart from one second light emitting region PXA-G in a fourth direction DR4. One first light emitting region PXA-B may be spaced apart from one second light emitting region PXA-G in a fifth direction DR5. The fourth direction DR4 may be a direction between the first direction DR1 and the second direction DR2. The fifth direction DR5 may cross the fourth direction DR4 and may be inclined with respect to the second direction DR2.

The arrangement structure of the light emitting regions PXA-B, PXA-G and PXA-R is not limited to the arrangement structure shown in FIG. 3. For example, in the light emitting regions PXA-B, PXA-G, and PXA-R, the first light emitting region PXA-B, the second light emitting region PXA-G, and the light third light emitting region PXA-R may be arranged sequentially and alternately in the first direction DR1. The shapes of the light emitting regions PXA-B, PXA-G, and PXA-R in a plan view are not limited to the embodiment shown in FIG. 3, and the light emitting regions PXA-B, PXA-G, and PXA-R may have different shapes.

Referring to FIG. 4, the display device DD may include a display panel DP and an optical structure layer PP, which are stacked in the third direction DR3. The display panel DP may include a base substrate BS, a circuit layer DP-CL provided on the base substrate BS, and a display element layer DP-EL. The display element layer DP-EL may include a pixel defining layer PDL, a light emitting element ED disposed between the pixel defining layers PDL or on the pixel defining layer PDL, and an encapsulation layer TFE disposed on the light emitting element ED.

The base substrate BS may be a member providing a base surface on which the display element layer DP-EL is disposed. The base substrate BS may be a glass substrate, a metal substrate, a plastic substrate, or the like. However, the disclosure is not limited thereto, and the base substrate BS may be an inorganic layer, an organic layer, or a complex material layer.

The base substrate BS may include a single- or multi-layered structure. For example, the base substrate BS may include a first synthetic resin layer, a multi-layered or single-layered intermediate layer, and a second synthetic resin layer, which are sequentially stacked. The intermediate layer may be referred to as a base barrier layer. The intermediate layer may include a silicon oxide (SiOₓ) layer and an amorphous silicon (a-Si) layer disposed on the silicon oxide layer, but the disclosure is not particularly limited thereto. For example, the intermediate layer may include at least one of a silicon oxide layer, a silicon nitride layer, a silicon oxynitride layer, or an amorphous silicon layer. The base substrate BS may be a flexible substrate that may be readily bendable or foldable.

The first and second synthetic resin layers may each include a polyimide-based resin. In an embodiment, the first and second synthetic resin layers may each include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. As used herein, a “˜˜based” resin may be considered as including a functional group of “˜”.

In an embodiment, the circuit layer DP-CL may be disposed on the base substrate BS, and the circuit layer DP-CL may include multiple transistors (not shown). The transistors (not shown) may each include a control electrode, an input electrode, and an output electrode. For example, the circuit layer DP-CL may include a switching transistor and a driving transistor for driving the light emitting element ED of the display element layer DP-EL.

The display element layer DP-EL may be disposed on the circuit layer DP-CL. The display element layer DP-EL may include a pixel defining layer PDL and first to third light emitting elements ED-1, ED-2, and ED-3, which are divided by the pixel defining layer PDL. The light emitting elements ED-1, ED-2, and ED-3 of the display element layer DP-EL may be electrically connected to driving elements of the circuit layer DP-CL, and may thus generate light according to signals provided by the driving elements to display images.

The first to third light emitting elements ED-1, ED-2, and ED-3 may emit light in different wavelength ranges. In another embodiment, the first to third light emitting elements ED-1, ED-2, and ED-3 may emit light in a same wavelength range, or one light emitting element may emit light in a different wavelength range from other light emitting elements.

The pixel defining layer PDL may be formed of a polymer resin. For example, the pixel defining layer PDL may include a polyacrylate-based resin or a polyimide-based resin. In an embodiment, the pixel defining layer PDL may further include an inorganic material in addition to the polymer resin. In an embodiment, the pixel defining layer PDL may include a light absorbing material, or a black pigment or a black dye. The pixel defining layer PDL including a black pigment or a black dye may implement a black pixel defining layer. When forming the pixel defining layer PDL, carbon black may be used as a black pigment or a black dye, but the disclosure is not limited thereto.

In an embodiment, the pixel defining layer PDL may be formed of an inorganic material. For example, the pixel defining layer PDL may be formed at least one of silicon nitride (SiNₓ), silicon oxide (SiOₓ), silicon oxynitride (SiOₓN_{y}), and the like.

The pixel defining layer PDL may have a pixel opening OH. A portion of a first electrode EL1 may be exposed by the pixel opening OH in a plan view. Portions corresponding to the first electrode EL1 exposed by the pixel opening OH may be defined as light emitting regions PXA-B, PXA-G, and PXA-R. However, the disclosure is not limited thereto.

The pixel defining layer PDL may separate the first to third light emitting elements ED-1, ED-2, and ED-3. The emission layers EML-B, EML-G, and EML-R of the light emitting elements ED-1, ED-2 and ED-3 may be disposed and separated in the pixel opening OH defined by the pixel defining layer PDL.

The first to third light emitting elements ED-1, ED-2, and ED-3 may each include a first electrode EL1, a second electrode EL2 facing the first electrode EL1, emission layers EML-B, EML-G, and EML-R disposed between the first electrode EL1 and the second electrode EL2, a functional layer FL disposed between the first electrode EL1 and the second electrode EL2, and a capping layer CPL disposed on the second electrode EL2. The functional layer FL may be disposed at least one of between the first electrode EL1 and the emission layers EML-B, EML-G, and EML-R and between the emission layers EML-B, EML-G, and EML-R and the second electrode EL2. In an embodiment, the first to third light emitting elements ED-1, ED-2, and ED-3 may each include a first electrode EL1, a first functional layer FL-B, emission layers EML-B, EML-G, and EML-R, a second functional layer FL-T, a second electrode EL2, and a capping layer CPL, which are sequentially stacked in the third direction DR3. The capping layer CPL may be directly disposed on the second electrode EL2.

The first electrode EL1 may be exposed by the pixel opening OH of the pixel defining layer PDL. The first electrode EL1 may have conductivity. The first electrode EL1 may be formed of a metal material, a metal alloy or a conductive compound. The first electrode EL1 may be an anode or a cathode. In an embodiment, the first electrode EL1 may be a pixel electrode. However, the disclosure is not limited thereto.

The second electrode EL2 may be disposed on the first electrode EL1. The second electrode EL2 may be a cathode or an anode. In an embodiment, in case that the first electrode EL1 is an anode, the second electrode EL2 may be a cathode, and in case that the first electrode EL1 is a cathode, the second electrode EL2 may be an anode. The second electrode EL2 may be a common electrode. However, the disclosure is not limited thereto.

One of a first functional layer FL-B disposed between the first electrode EL1 and the emission layers EML-B, EML-G, and EML-R and a second functional layer FL-T disposed between the emission layers EML-B, EML-G, and EML-R and the second electrode EL2 may be a hole transport region, and another one may be an electron transport region. Referring to FIG. 4, the first functional layer FL-B and the second functional layer FL-T may be provided as a common layer throughout the light emitting regions PXA-B, PXA-G, and PXA-R. In an embodiment, the functional layer FL may overlap both the emission layers EML-B, EML-G, and EML-R and the pixel defining layer PDL in the third direction DR3. However, the disclosure is not limited to thereto, and at least one of the first functional layer FL-B or the second functional layer FL-T may overlap the emission layers EML-B, EML-G, and EML-R in the third direction DR3, and may be patterned and provided in a pixel opening OH.

The encapsulation layer TFE may be disposed on the display element layer DP-EL. The encapsulation layer TFE may include an organic material or an inorganic material. The encapsulation layer TFE may have a multi-layer structure in which an inorganic layer and an organic layer are repeated. In an embodiment, the encapsulation layer TFE may include a first inorganic layer IOL1, an organic layer OL, and a second inorganic layer IOL2, which are sequentially stacked. However, the layers constituting the encapsulation layer TFE are not limited thereto. The encapsulation layer TFE may be directly provided on the light emitting element ED through a roll-to-roll process. In an embodiment, the encapsulation layer TFE may be directly provided on the capping layer CPL.

The first inorganic layer IOL1 and the second inorganic layer IOL2 may protect the light emitting element ED against moisture and oxygen, and the organic layer OL may protect the light emitting element ED against foreign substances such as dust particles. For example, the organic layer OL may prevent dent defects on the light emitting element ED caused by foreign substances introduced during the manufacturing process. Although not shown, the display device DD may further include a refractive index control layer disposed on an upper side of the encapsulation layer TFE to increase light output efficiency.

The first inorganic layer and the second inorganic layer IOL1 and IOL2 may include at least one of silicon nitride, silicon oxynitride, silicon oxide, titanium oxide, or aluminum oxide. The organic layer OL may include an acryl-based organic material. However, the types of materials constituting the inorganic layers IOL1 and IOL2 and the organic layer OL are not limited thereto.

Referring to FIG. 4, the display device DD of an embodiment may include an optical structure layer PP disposed on the display panel DP. The optical structure layer PP may include a base layer BL and a color filter layer CFL.

The base layer BL may be a member providing a base surface on which the color filter layer CFL is disposed. The base layer BL may be a glass substrate, a metal substrate, a plastic substrate, or the like. However, the disclosure is not limited thereto, and the base layer BL may be an inorganic layer, an organic layer, or a complex material layer.

The color filter layer CFL may include filters CF-B, CF-G, and CF-R. The color filter layer CFL may include first to third filters CF-B, CF-G, and CF-R. The first to third filters CF-B, CF-G, and CF-R may each be arranged to correspond to the first to third light emitting elements ED-1, ED-2, and ED-3. For example, the first filter CF-B may be a blue filter, the second filter CF-G may be a green filter, and the third filter CF-R may be a red filter. The first to third filters CF-B, CF-G, and CF-R may each be arranged to correspond to each of the first to third pixel regions PXA-B, PXA-G, and PXA-R.

In an embodiment, the filters CF-B, CF-G, and CF-R that transmit different light may overlap the peripheral region NPXA disposed between the light emitting regions PXA-B, PXA-G, and PXA-R. The filters CF-B, CF-G, and CF-R may overlap each other in the third direction DR3, which is the thickness direction, to separate boundaries between the adjacent light emitting regions PXA-B, PXA-G, and PXA-R. Accordingly, the effect of blocking external light may increase, and the filters CF-B, CF-G, and CF-R may serve as a black matrix. The overlapping structure of the filters CF-B, CF-G, and CF-R may serve to prevent color mixing.

The first to third filters CF-B, CF-G, and CF-R may each include a polymer photosensitive resin and a pigment or a dye. The first filter CF-B may include a blue pigment or a blue dye, the second filter CF-G may include a green pigment or a green dye, and the third filter CF-R may include a red pigment or a red dye. However, the disclosure is not limited thereto, and the first filter CF-B may not include a pigment or a dye. The first filter CF-B may include a polymer photosensitive resin, but not include a pigment or a dye. The first filter CF-B may be transparent. The first filter CF-B may be formed of a transparent photosensitive resin.

The color filter layer CFL may further include a buffer layer BFL. For example, the buffer layer BFL may be a protection layer protecting the first to third filters CF-B, CF-G, and CF-R. The buffer layer BFL may be an inorganic material layer including at least one of silicon nitride, silicon oxide, and silicon oxynitride. The buffer layer BFL may be formed of a single layer or multiple layers.

In an embodiment, the second filter CF-G and the third filter CF-R may be yellow filters. The second filter CF-G and the third filter CF-R may not be separated from each other and may be provided as a single body.

Although not shown, the color filter layer CFL may further include a light blocking unit (not shown). The light blocking unit may be a black matrix. The light blocking unit may include an organic light blocking material or an inorganic light blocking material, both including a black pigment or a black dye. The light blocking unit may prevent light leakage, and separate boundaries between the adjacent filters CF-B, CF-G, and CF-R. The light blocking unit (not shown) may overlap the pixel defining layer PDL in the third direction DR3 and correspond to the peripheral region NPXA. In another embodiment, unlike what is shown in FIG. 4 and the like, the optical structure layer PP of the display device DD may not include the color filter layer CFL.

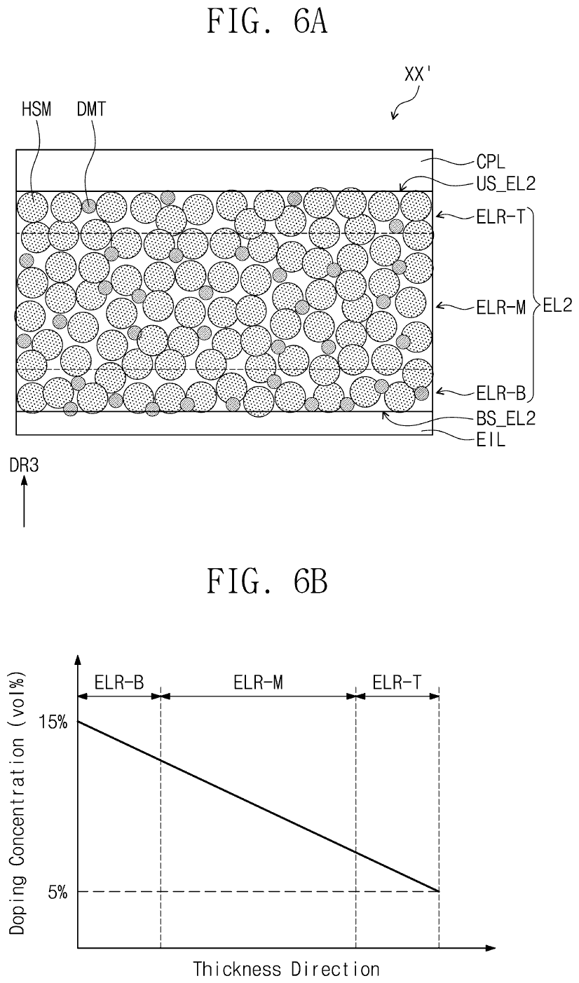

FIG. 5 is a schematic cross-sectional view showing a light emitting element according to an embodiment. The structure of light emitting element ED described with reference to FIG. 5 may be applied to at least one of the first to third light emitting elements ED-1, ED-2, and ED-3 shown in FIG. 4. In FIG. 5, the light emitting element ED of an embodiment may include a first electrode EL1, at least one light emitting structure EU, a second electrode EL2, and a capping layer CPL, which are sequentially stacked in the third direction DR3. The light emitting structure EU may include an emission layer EML.

In the light emitting element ED according to an embodiment of the disclosure shown in FIG. 5 and the like, one light emitting structure EU is shown to be disposed between the first electrode EL1 and the second electrode EL2, but the disclosure is not limited thereto. For example, in another embodiment, multiple light emitting structures may be disposed between the first electrode EL1 and the second electrode EL2, each light emitting structure EU may include an emission layer EML, and a charge generation layer (not shown) may be disposed between the light emitting structures EU. The charge generation layer (not shown) may generate charges (electrons and holes) and provide the charges to each of the adjacent light emitting structures EU.

In an embodiment shown in FIG. 5, the light emitting element ED may include a first electrode EL1, a first functional layer FL-B, an emission layer EML, a second functional layer FL-T, a second electrode EL2, and a capping layer CPL. In an embodiment, the first functional layer FL-B may be a hole transport region, and the second functional layer FL-T may be an electron transport region. For example, in the first to third light emitting elements ED-1, ED-2, and ED-3 shown in FIG. 4, the first functional layer FL-B may be a hole transport region, and the second functional layer FL-T may be an electron transport region.

In the light emitting element ED shown in FIG. 5, the first electrode EL1 may be an anode, and the second electrode EL2 may be a cathode. In an embodiment, the first electrode EL1 may be a reflective electrode, and the second electrode EL2 may be a transmissive electrode or a transflective electrode. The light emitting element ED of an embodiment may have a top emission light emitting structure in which light is emitted above the second electrode EL2.

In an embodiment, the first electrode EL1 may be a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, a compound thereof, a mixtures thereof, and an oxide thereof.

The first electrode EL1 may include a transparent metal oxide such as indium tin oxide (ITO), indium zinc oxide (IZO), zinc oxide (ZnO), and indium tin zinc oxide (ITZO). In an embodiment, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., a mixture of Ag and Mg). In another embodiment, the first electrode EL1 may have a multi-layer structure including a reflective film or a transflective film formed of the above-described material, and a transparent conductive film formed of indium tin oxide (ITO), indium zinc oxide (IZO), zinc oxide (ZnO), indium tin zinc oxide (ITZO), or the like. For example, the first electrode EL1 may have a three-layer structure of ITO/Ag/ITO, but the disclosure is not limited thereto. In an embodiment, the first electrode EL1 may include the above-described metal material, a combination of the above-described metal material, or an oxide of the above-described metal material, but the disclosure is not limited thereto. The first electrode EL1 may have a thickness in a range of about 700 Å to about 10000 Å. For example, the first electrode EL1 may have a thickness in a range of 1000 Å to about 3000 Å.

A hole transport region may be disposed as the first functional layer FL-B (hereinafter referred to as a hole transport region) on the first electrode EL1. In the light emitting element ED according to an embodiment, the hole transport region FL-B may include at least one of a hole injection layer HIL or a hole transport layer HTL. The hole transport region FL-B may have a layer formed of a material, a layer formed of different materials, or a multi-layer structure having multiple layers formed of different materials. The hole injection layer HIL and the hole transport layer HTL may each have a single-layer structure or a multi-layer structure. The hole transport region FL-B may further include a component such as an electron blocking layer and a buffer layer, in addition to the hole injection layer HIL and the hole transport layer HTL.

The hole transport region FL-B may be formed by a method such as a vacuum deposition method, a spin coating method, a cast method, a Langmuir-Blodgett (LB) method, an inkjet printing method, a laser printing method, and a laser induced thermal imaging (LITI) method.

The hole transport region FL-B may include a hole injection material and/or a hole transport material. For example, the hole transport region FL-B may include at least one of a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-tris (N,N-diphenylamino) triphenylamine (TDATA), 4,4′,4″-tris [N (2-naphthyl)-N-phenylamino]-triphenylamine (2-TNATA), poly(3,4-ethylenedioxythiophene)/poly(4-styrenesulfonate) (PEDOT/PSS), polyaniline/Dodecylbenzenesulfonic acid (PANI/DBSA), polyaniline/camphor sulfonicacid (PANI/CSA), polyaniline/poly(4-styrenesulfonate) (PANI/PSS), N,N′-di (naphthalene-1-yl)-N,N′-diphenyl-benzidine (NPB), triphenylamine-containing polyetherketone (TPAPEK), 4-isopropyl-4′-methyldiphenyliodonium tetrakis (pentafluorophenyl) borate, dipyrazino[2,3-f: 2′,3′-h] quinoxaline-2,3,6,7,10,11-hexacarbonitrile (HATCN), and the like.

In an embodiment, the hole transport region FL-B may include at least one of a carbazole-based derivative such as N-phenyl carbazole and polyvinyl carbazole, a fluorene-based derivative, N,N′-bis(3-methylphenyl)-N,N′-diphenyl-[1,1-biphenyl]-4,4′-diamine (TPD), a triphenylamine-based derivative such as 4,4′,4″-tris(N-carbazolyl) triphenylamine (TCTA), N,N′-di (1-naphtalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP), and the like.

The hole transport region FL-B may have a thickness in a range of about 5 nm to about 1,500 nm. For example, the hole transport region FL-B may have a thickness in a range of about 10 nm to about 500 nm. In case that the thickness of the hole transport region FL-B satisfies the above-described range, satisfactory hole transport properties may be obtained without a substantial increase in driving voltage.

In the light emitting element ED of an embodiment, the emission layer EML may be disposed on the hole transport region FL-B. In the light emitting element ED according to an embodiment, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

The emission layer EML may include a host and a dopant. For example, the emission layer EML may include, as a host material, at least one of bis(4-(9H-carbazol-9-yl)phenyl) diphenylsilane (BCPDS), (4-(1-(4-(diphenylamino)phenyl) cyclohexyl)phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, the disclosure is not limited thereto, and in another embodiment, tris(8-hydroxyquinolino) aluminum (Alq₃), 9,10-di(naphthalene-2-yl) anthracene (ADN), 3-tert-butyl-9,10-di(naphth-2-yl) anthracene (TBADN), distyrylarylene (DSA), 4,4′-bis(9-carbazolyl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), or the like may be used as a host material.

The emission layer EML may include, as a dopant material, at least one of a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), a perylene or a perylene derivative (e.g., 2,5,8,11-tetra-t-butylperylene (TBP)), a pyrene or a pyrene derivative (e.g., 1,1-dipyrene, 1,4-dipyrenylbenzene, 1,4-bis(N,N-diphenylamino) pyrene), and the like.

The emission layer EML may further include a phosphorescent dopant material. For example, as a phosphorescent dopant, a metal complex including iridium (Ir), platinum (Pt), osmium (Os), gold (Au), titanium (Ti), zirconium (Zr), hafnium (Hf), europium (Eu), and terbium (Tb), or thulium (Tm) may be used. For example, iridium (III) bis(4,6-difluorophenylpyridinato-N,C2′) picolinate (FIrpic), bis(2,4-difluorophenylpyridinato)-tetrakis (1-pyrazolyl) borate iridium (III) (Fir6), platinum octaethyl porphyrin (PtOEP), or the like may be used as a phosphorescent dopant. However, the disclosure is not limited thereto.

In an embodiment, the emission layer EML may include quantum dots as a light emitting material.

In an embodiment shown in FIG. 5, the emission layer EML may include a main emission layer EL_M and an auxiliary emission layer EL_S. The main emission layer EL_M and the auxiliary emission layer EL_S may include different materials.

In an embodiment, the main emission layer EL_M may include a host and a dopant material to emit light in a specific wavelength range. In an embodiment, the auxiliary emission layer EL_S may include a material for compensating a resonance distance according to the wavelength of light emitted from the emission layer EML and regulating a hole charge balance to increase light emitting efficiency. The emission layers EML-B, EML-G, and EML-R of the first to third light emitting elements ED-1, ED-2, and ED-3 of the display element layer DP-EL shown in FIG. 4 may each include a main emission layer EL_M. The emission layers EML-B, EML-G, and EML-R of the first to third light emitting elements ED-1, ED-2, and ED-3 may include different main emission layer materials.

In an embodiment, the presence or absence of the auxiliary emission layer EL_S and a thickness of the auxiliary emission layer EL_S may be regulated according to an emission wavelength range of the main emission layer EL_M. For example, in the structure of the display element layer DP-EL according to an embodiment shown in FIG. 4, the first emission layer EML-B of the first light emitting element ED-1 that emits blue light may include no auxiliary emission layer EL_S, the second emission layer EML-G of the second light emitting element ED-2 that emits green light and the third emission layer EML-R of the third light emitting element ED-3 that emits red light may each include an auxiliary emission layer EL_S. In an embodiment, the auxiliary emission layer EL_S included in the third light emitting element ED-3 may be thicker than the auxiliary emission layer EL_S included in the second light emitting element ED-2 in the third direction DR3.

In FIG. 5, a thickness of the main emission layer EL_M and a thickness of the auxiliary emission layer EL_S are shown to be similar, but the disclosure is not limited thereto, and in another embodiment, the auxiliary emission layer EL_S may be thicker than the main emission layer EL_M.

In the light emitting element ED of an embodiment, an electron transport region may be disposed as a second functional layer FL-T (hereinafter referred to as an electron transport region) on the emission layer EML. The electron transport region FL-T may include at least one of an electron transport layer ETL and an electron injection layer EIL, but the disclosure is not limited thereto.

The electron transport region FL-T may have a layer formed of a material, a layer formed of different materials, or a multi-layer structure having multiple layers formed of different materials. For example, the electron transport region FL-T may have a single-layer structure of an electron injection layer EIL or an electron transport layer ETL, or may have a single-layer structure formed of an electron injection material and an electron transport material. The electron injection layer EIL and electron transport layer ETL may each have a single-layer structure or a multi-layer structure. The electron transport region FL-T may further include a component such as a hole blocking layer and a buffer layer, in addition to the electron injection layer EIL and the electron transport layer ETL. The electron transport region FL-T may have a thickness in a range of, for example, about 20 nm to about 150 nm.

The electron transport region FL-T may be formed by a method such as a vacuum deposition method, a spin coating method, a cast method, a Langmuir-Blodgett (LB) method, an inkjet printing method, a laser printing method, and a laser induced thermal imaging (LITI) method.

The electron transport region FL-T may include an electron injection material and/or an electron transport material. For example, the electron transport region FL-T may include an anthracene-based compound. In another embodiment, the electron transport region FL-T may include, for example, tris(8-hydroxyquinolinato)aluminum (Alq₃), 1,3,5-tri[(3-pyridyl)-phen-3-yl]benzene, 2,4,6-tris(3-(pyridin-3-yl) biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1-biphenyl-4-olato)aluminum (BAlq), berylliumbis(benzoquinolin-10-olate (Bebq₂), 9,10-di(naphthalene-2-yl) anthracene (ADN), 1,3-bis[3,5-di (pyridin-3-yl) phenyl]benzene (BmPyPhB), or a mixture thereof. In another embodiment, the electron transport region FL-T may include 2,9-dimethyl-4,7-diphenyl-1,10-phenanthroline (BCP), diphenyl (4-(triphenylsilyl)phenyl) phosphine oxide (TSPO1), 4,7-diphenyl-1,10-phenanthroline (Bphen), or the like.

In an embodiment, the electron transport region FL-T may include a halogenated metal such as LiF, NaCl, CsF, RbCl, RbI, CuI, and KI, a lanthanide metal such as Yb, or a co-deposition material of a halogenated metal and a lanthanide metal. For example, the electron transport region FL-T may include KI: Yb, RbI: Yb, LiF: Yb, or the like as a co-deposition material. In an embodiment, for the electron transport region FL-T, a metal oxide such as Li₂O and BaO, or 8-hydroxyl-lithium quinolate (Liq), or the like may be used, but the disclosure is limited thereto. In an embodiment, the electron transport region FL-T may be formed of a mixture of an electron transport material and an insulating organo-metal salt. The organo-metal salt may be a material having an energy band gap greater than or equal to about 4 eV. For example, the organo-metal salt may include, for example, a metal acetate, a metal benzoate, a metal acetoacetate, a metal acetylacetonate, or a metal stearate.

The second electrode EL2 may be disposed on the electron transport region FL-T. In an embodiment, the second electrode EL2 may be directly disposed on the electron transport region FL-T. In an embodiment, the second electrode EL2 may be directly disposed on the electron injection layer EIL including KI: Yb, RbI: Yb, LiF: Yb, or the like.

The second electrode EL2 may be a transmissive electrode or a transflective electrode. The second electrode EL2 may include a metal host and a metal dopant. The second electrode EL2 may be formed by mixing two or more types of metals, such as a metal host and a metal dopant.

In an embodiment, the metal host of the second electrode EL2 may be silver (Ag). The second electrode EL2 may include Ag and a metal dopant. In an embodiment, the metal dopant of the second electrode EL2 may include at least one of Al, Au, Cu, Mg, Ti, In, Ni, C, Pd, F, Na, Si, Ca, Mn, Fe, Co, Zn, Ga, Ge, Mo, Sn, In, Pt, Pb, Fe, Yb, Lu, and Pa. For example, the metal dopant of the second electrode EL2 may be Mg, Al, Cu, Ca, or Ba. For example, the second electrode EL2 may include Ag, and Mg as a metal dopant.

The second electrode EL2 may be formed using a method of thermal evaporation. The second electrode EL2 may be formed by co-deposition of a metal host and a metal dopant. The metal dopant may improve the performance of the metal host, which is the main electrode material, in film formation through thermal evaporation. For example, in the forming of the second electrode EL2 by co-deposition of Ag as a metal host and Mg as a metal dopant by thermal evaporation, an Ag island formed by aggregating Ag by a metal dopant MG may be prevented from forming. Accordingly, in case that the metal dopant is co-deposited with Ag, the second electrode EL2 having excellent thin film uniformity and stability may be formed even using thermal evaporation.

The second electrode EL2 may have a thickness in a range of about 50 Å to about 300 Å. In case that the second electrode EL2 is formed using thermal evaporation, the second electrode EL2 may be provided with uniform thin film characteristics at a thickness in a range of about 50 Å to about 300 Å.

The capping layer CPL may be disposed on the second electrode EL2 of the light emitting element ED. The capping layer CPL may include a multi-layer or a single layer. The capping layer CPL may be directly disposed on the second electrode EL2.

In an embodiment, the capping layer CPL may be an organic layer or an inorganic layer. For example, in case that the capping layer CPL includes an inorganic material, the inorganic material may include an alkali metal compound such as LiF, an alkaline earth metal compound such as MgF₂, SiON, SiN_{X}, SiO_{y}, and the like.

For example, in case that the capping layer CPL includes an organic material, the organic material may include a-NPD, NPB, TPD, m-MTDATA, Alq₃ CuPc, N4,N4,N4′,N4′-tetra (biphenyl-4-yl) biphenyl-4,4′-diamine (TPD15), 4,4′,4″-tris(carbazol sol-9-yl)triphenylamine (TCTA), or the like, or may include an epoxy resin or an acrylate such as methacrylate. However, the disclosure is not limited thereto, and in another embodiment, the capping layer CPL may include compounds P1 to P5 below.

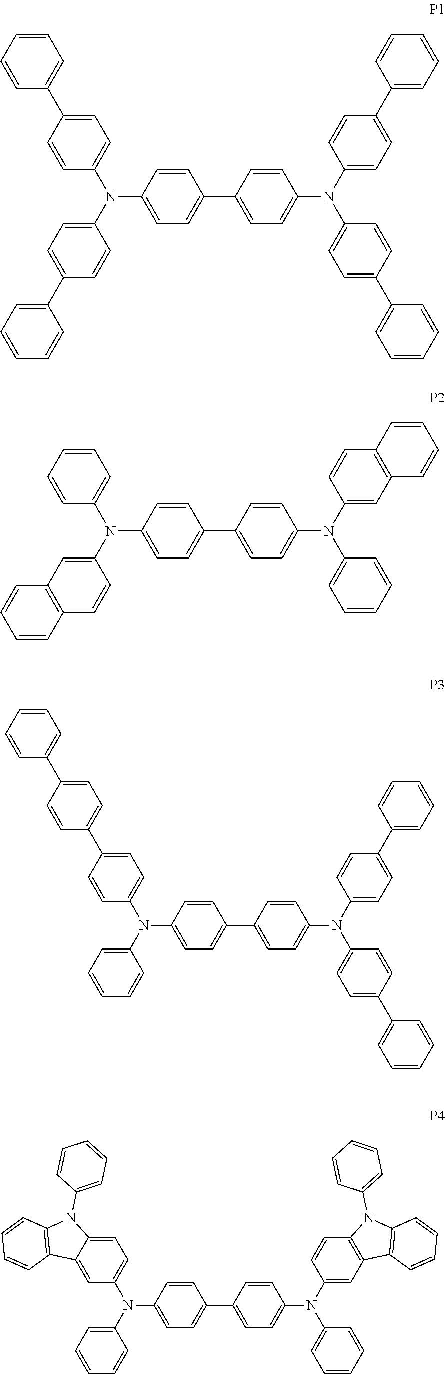 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

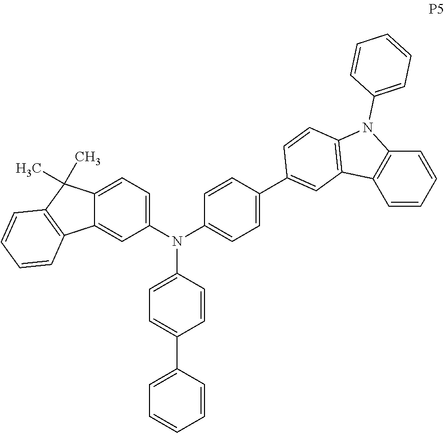 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In an embodiment, the capping layer CPL may have a refractive index greater than or equal to about 1.6. For example, the capping layer CPL may have a refractive index greater than or equal to about 1.6 in a wavelength in range of about 550 nm to about 660 nm.

In case that the second electrode EL2 is formed by co-deposition of a metal host and a metal dopant, the metal host and the metal dopant may be different in deposition rate. A ratio of the metal host and the metal dopant in the second electrode EL2 may be regulated by varying the deposition rate of the metal host and the metal dopant. In an embodiment, the ratio of the metal dopant in the second electrode EL2 may be different depending on location.

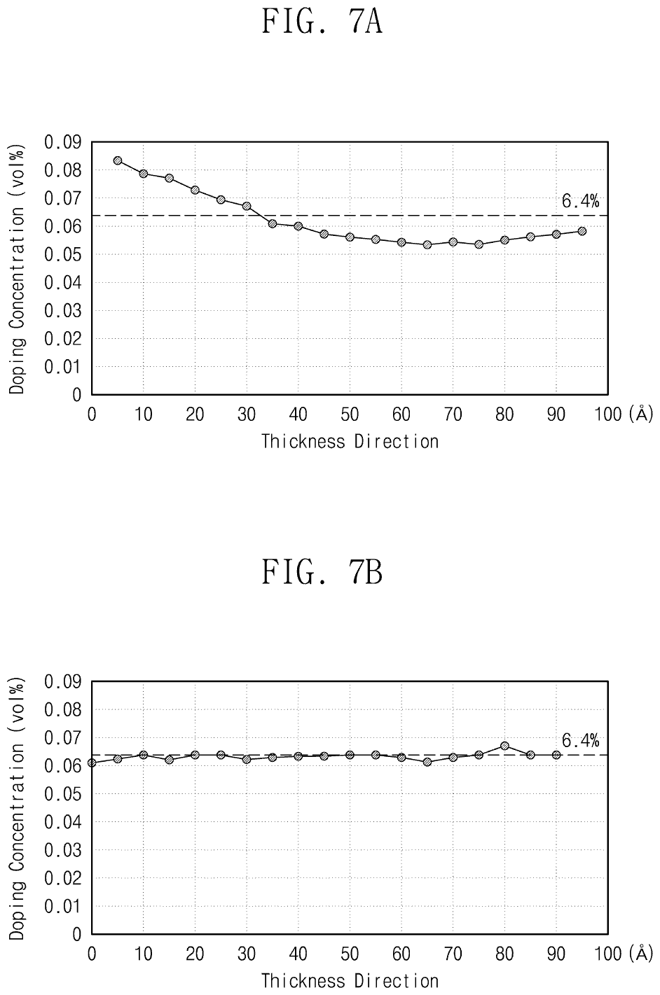

FIG. 6A is a schematic cross-sectional view enlarging a portion of a light emitting element of an embodiment. FIG. 6A is a view schematically showing enlarged region XX′ of FIG. 5. FIG. 6B is a graph showing a doping concentration of a metal dopant along a thickness direction in an embodiment shown in FIG. 6A.

Referring to FIG. 6A, the second electrode EL2 may include a metal host HSM and a metal dopant DMT. The metal dopant DMT may be distributed throughout the second electrode EL2. The metal host HSM may be Ag. For example, the entire second electrode EL2 may be a layer formed by co-deposition of Ag and the metal dopant DMT.

Referring to FIGS. 6A and 6B, in an embodiment, a ratio of metal dopant DMT may gradually decrease in a direction from the light emitting structure EU (FIG. 5) toward the capping layer CPL. In an embodiment, the ratio of metal dopant DMT or the concentration of metal dopant DMT may correspond to a volume ratio. The volume ratio of the metal dopant DMT in the second electrode EL2 may correspond to a volume ratio of the metal host HSM with respect to a total volume (100) of the second electrode EL2. An average volume ratio of the metal dopant DMT in the second electrode EL2 may correspond to a ratio of the metal dopant DMT with respect to a total volume (100) of the second electrode EL2.

Referring to FIGS. 6A and 6B, a volume ratio of the metal dopant DMT in a first region ELR-T of the second electrode EL2 adjacent to a first surface US_EL2 in contact with the capping layer CPL may be less than the average volume ratio of the metal dopant DMT in the electrode EL2.

In an embodiment, the ratio of the metal dopant DMT in the region adjacent to the capping layer CPL may be smaller than the ratio of the metal dopant DMT in other regions of the second electrode EL2, and accordingly, diffusion of the metal dopant DMT having a smaller work function and a relatively smaller atomic diameter than the metal host HSM into adjacent layers or interfaces with adjacent layers may be minimized.

For example, degradation in interface properties between the capping layer CPL and the second electrode EL2 due to movement of the metal dopant DMT, which is caused upon prolonged exposure to ultraviolet rays (UV) or prolonged use in an external environment, may be improved. In an embodiment, the volume ratio of the metal dopant DMT in the region adjacent to the capping layer CPL may be less than the average volume ratio of the metal dopant DMT in an entire area of the second electrode EL2, and accordingly, damage to interface due to movement of the metal dopant DMT to the interface and subsequent exciton quenching may be minimized to prevent reduction in optical efficiency and element service life. In an embodiment, the metal dopant DMT may be included at a relatively low volume ratio in the region adjacent to the capping layer CPL, thereby minimizing the movement of metal dopants DMT to the interface with adjacent layers, and accordingly, roughness of the interface may remain uniform to prevent diffuse reflection, and the like, resulting in excellent optical properties and light efficiency characteristics.

The average volume ratio of the metal dopant DMT in the second electrode EL2 may be less than or equal to about 30%. For example, with respect to the volume (100) of the entire metal host HSM and the entire metal dopant DMT constituting the second electrode EL2, the volume ratio of the metal dopant DMT may be less than or equal to about 30%. In an embodiment, the average volume ratio of the metal dopant DMT may be greater than or equal to about 3%. For example, in an embodiment, the average volume ratio of the metal dopant may be in a range of about 3% to about 10%.

In an embodiment, in case that the metal host HSM is Ag and the metal dopant DMT is Mg, the average volume ratio of Mg in the second electrode EL2 may be in a range of about 3% to about 10%.

The second electrode EL2 may include a first region ELR-T including a first surface US_EL2 in contact with the capping layer CPL, a second region ELR-B including a second surface BS_EL2 in contact with the light emitting structure EU (FIG. 5), and a third region ELR-M disposed between the first region ELR-T and the second region ELR-B. A thickness of the first region ELR-T and a thickness of the second region ELR-B may each be less than a third of a total thickness of the second electrode EL2 in the third direction DR3. In an embodiment, the second electrode EL2 may have a thickness in a range of about 50 Å to about 300 Å. The second electrode EL2 has a thickness in a range of about 50 Å to about 300 Å, and accordingly, the second electrode EL2 may have optical characteristics of high transmittance and low surface resistance.

In FIG. 6B, the thickness direction may be a direction in the third direction DR3. Referring to FIGS. 6A and 6B, the ratio of the metal dopant DMT may gradually decrease along the third direction DR3, which is the thickness direction. In FIG. 6B and the drawings below, the doping concentration is used in the same sense as the volume ratio of the metal dopant.

Referring to FIG. 6B, in an embodiment, the doping concentration of the metal dopant DMT may decrease from the second region ELR-B to the first region ELR-T. In an embodiment shown in FIG. 6B, the doping concentration of the metal dopant DMT may be gradually reduced from about 15% to about 5%, and the average volume ratio of the metal dopant in the second electrode EL2 may be about 10%. FIG. 6B shows a profile of the doping concentration of the metal dopant in the second electrode EL2 as an embodiment.

The doping concentration of the metal dopant DMT may be regulated by varying the deposition rate of materials for deposition. The volume ratio of the metal host HSM and the metal dopant DMT may be determined according to the ratio of the respective deposition rates of the metal host HSM and the metal dopant DMT. For example, in the embodiment shown in FIG. 6B, the ratio of the deposition rates of the metal host HSM and the metal dopant DMT may change from about 0.85 (Å/sec): 0.15 (Å/sec) to about 0.95 (Å/sec): 0.05 (Å/sec).

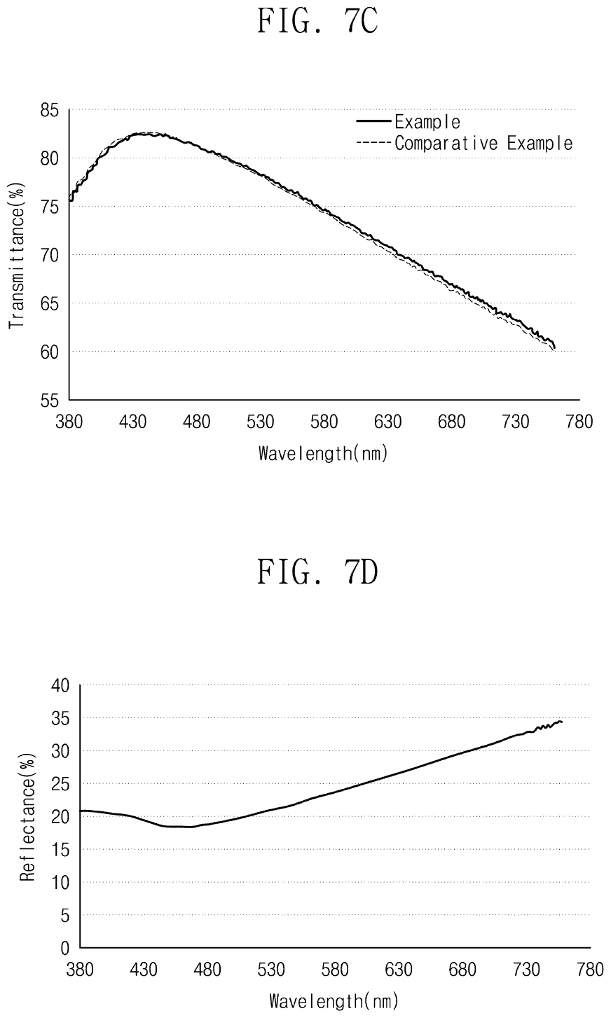

FIG. 7A is a graph showing a doping concentration of a metal dopant along a thickness direction in a second electrode in Example, and FIG. 7B is a graph showing a doping concentration of a metal dopant along a thickness direction in a second electrode in Comparative Example. The thickness direction in FIGS. 7A and 7B may correspond to the third direction DR3 in FIG. 6A. In FIGS. 7A and 7B, 0 Å on the horizontal axis indicated in the thickness direction corresponds to the interface between the electron injection layer EIL (FIG. 6A) and the second electrode EL2 (FIG. 6A), and in FIGS. 7A and 7B, 100 Å on the horizontal axis indicated in the thickness direction corresponds to the interface between the second electrode EL2 (FIG. 6A) and the capping layer CPL (FIG. 6A).

In both FIGS. 7A and 7B, the average volume ratio of the metal dopant in the second electrode is 6.4%. FIG. 7A shows Example in which the second electrode is formed in a direction in which the doping concentration of the metal dopant is gradually reduced along the thickness direction, and FIG. 7B shows Comparative Example in which the doping concentration of the metal dopant is maintained at a uniform level throughout the entire thickness.

FIG. 7C is a graph showing a comparison of transmittance characteristics in Example and Comparative Example. Referring to FIG. 7C, in transmittance characteristics, Example in which the deposition rate of the metal dopant is changed so that the volume ratio of the metal dopant in the region adjacent to the capping layer in the second electrode is less than the average volume ratio is shown to be similar to Comparative Example in which the metal dopant is deposited at a uniform deposition rate. In an embodiment, the second electrode may have a transmittance greater than or equal to about 70% at about 550 nm. Accordingly, the second electrode may be used as a transmissive electrode or a transflective electrode.

FIG. 7D is a graph showing a reflectance characteristics of a second electrode according to an embodiment having the doping concentration profile of FIG. 7A. Referring to FIG. 7D, in an embodiment, the reflectance of the second electrode may be less than or equal to about 30% at about 550 nm.

For example, a light emitting element including the second electrode according to an embodiment formed by varying the doping concentration ratio of the metal dopant depending on the thickness position may have high transmittance and low reflectance, and may be used as an upper electrode material of a top emission light emitting element. In an embodiment, a light emitting element having the second electrode according to an embodiment may have optical properties similar to the second electrode of Comparative Example having a uniform doping concentration of a metal dopant in the second electrode.

The second electrode EL2 according to an embodiment having the metal dopant doping profile of FIG. 7A may have a sheet resistance of about 11 (Q/u). This corresponds to electrical properties similar to the electrical properties of Comparative Example having a uniform doping concentration of a metal dopant in the second electrode.

The light emitting element of an embodiment may include a second electrode in which the volume ratio of the metal dopant in a region including a surface directly disposed below the capping layer and in contact with the capping layer is less than the average volume ratio, and may thus have similar electrical and optical properties to the second electrode in which the metal dopant is uniformly disposed in the entire region of the second electrode. In an embodiment, in the light emitting element of an embodiment, a relatively low doping concentration of a metal dopant in a region adjacent to an interface with the capping layer may be provided, so that a movement or a placement of the metal dopant to the interface with the capping layer upon prolonged external exposure or exposure to UV environment may be minimized to prevent element deterioration and reduction in luminous efficiency, resulting in excellent reliability.

In an embodiment, a display device of an embodiment including the light emitting element having the structure of the second electrode according to an embodiment shown in FIG. 6A and the like may have excellent display quality and improved reliability.

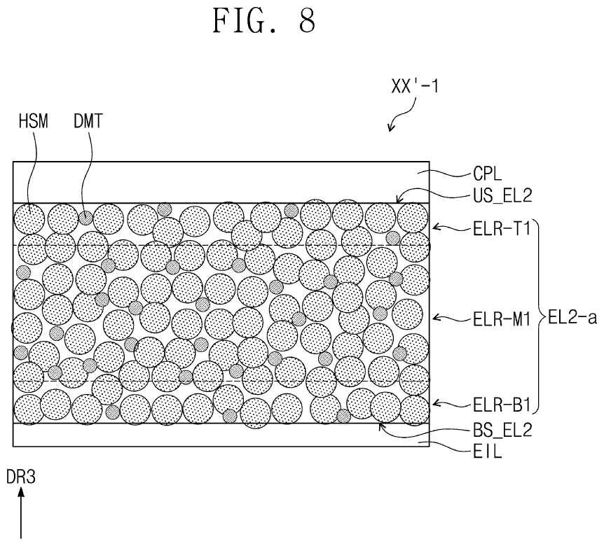

Hereinafter, a light emitting element according to an embodiment will be described with reference to FIGS. 8 to 11B. In the description of FIGS. 8 to 11B, content overlapping the embodiment described with reference to FIGS. 1 to 7D will not be described again, and differences will be described.

FIG. 8 is a schematic cross-sectional view enlarging a portion of a light emitting element according to an embodiment. Region XX′-1 in FIG. 8 may correspond to region XX′ in FIG. 5.

Referring to FIG. 8, in the light emitting element of an embodiment, a second electrode EL2-a may include a first region ELR-T1 including a first surface US_EL2 in contact with the capping layer CPL, a second region ELR-B1 including a second surface BS_EL2 in contact with the light emitting structure EU (FIG. 5), and a third region ELR-M1 disposed between the first region ELR-T1 and the second region ELR-B1.

The metal dopant DMT may be distributed throughout the first region ELR-T1, the second region ELR-B1, and the third region ELR-M1. The volume ratio of the metal dopant DMT in the first region ELR-T1 and the second region ELR-B1 may be less than the average volume ratio of the metal dopant DMT in the second electrode EL2-a. In an embodiment, the volume ratio of the metal dopant in the third region ELR-M1 may be greater than the average volume ratio of the metal dopant DMT in the second electrode EL2-a.

The second electrode EL2-a may be formed by co-deposition of the metal host HSM and the metal dopant DMT using thermal evaporation. The ratio of deposition rates of the metal host HSM and the metal dopant DMT may vary in the second region ELR-B1, the third region ELR-M1, and the first region ELR-T1 of the second electrode EL2-a according to an embodiment shown in FIG. 8. In an embodiment, the deposition rate of the metal dopant DMT in the third region ELR-M1 may be greater than the deposition rate of the metal dopant DMT in each of the first region ELR-T1 and the second region ELR-B1. Accordingly, the concentration (volume ratio) of the metal dopant DMT in the third region ELR-M1 of the second electrode EL2-a may be greater than the concentration (volume ratio) of the metal dopant DMT in each of the first region ELR-T1 and the second region ELR-B1 of the second electrode EL2-a.

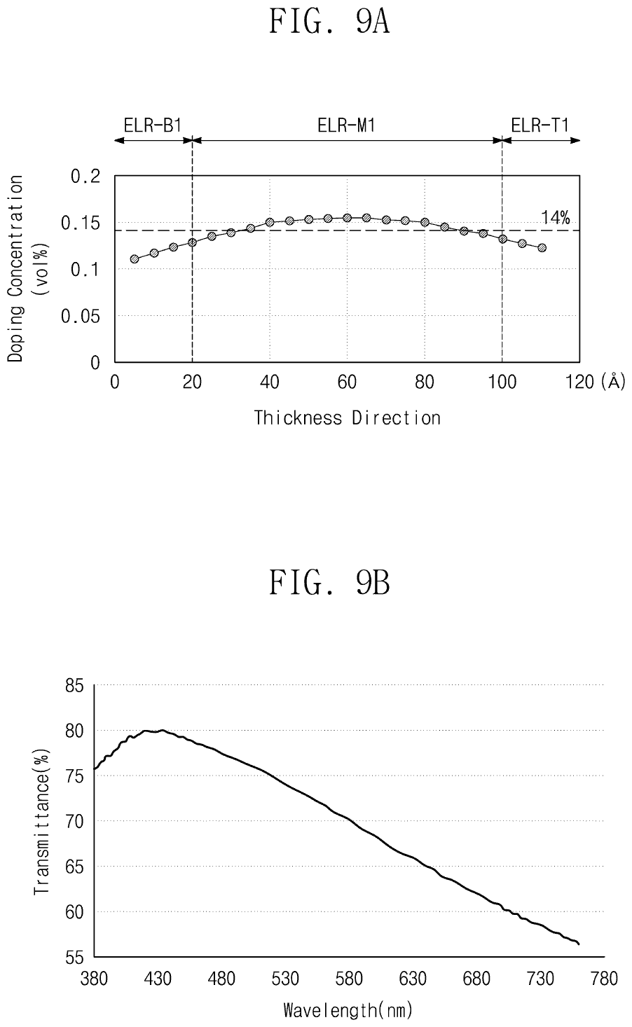

FIG. 9A is a graph showing a doping concentration profile along the thickness direction of the second electrode in a light emitting element having the structure of an embodiment shown in FIG. 8. FIG. 9B is a graph showing the transmittance characteristics of Example having the doping concentration profile shown in FIG. 9A.

Referring to FIG. 9A, the doping concentration of the metal dopant in the thickness direction of the second electrode in an embodiment may have a profile in which the middle portion is formed to be convex. In an embodiment, the average doping concentration of the metal dopant DMT in the second electrode CL2-a may be about 14%, and the second region ELR-B1 and the first region ELR-T1 may have a doping concentration lower than the average doping concentration of 14%. In an embodiment, the third region ELR-M1 may have a doping concentration higher than the average doping concentration of 14%. The second electrode EL2-a (FIG. 8) having the doping concentration profile shown in FIG. 9A may have a deposition rate of the metal dopant DMT less than or equal to about 0.14 (Å/sec) in the second region ELR-B1, a deposition rate of the metal dopant DMT greater than or equal to about 0.14 (Å/sec) in the third region ELR-M1, and a deposition rate of the metal dopant DMT less than or equal to about 0.14 (Å/sec) in the first region ELR-T1.

FIG. 9B shows transmittance characteristics of the embodiment in which the deposition rate of the metal dopant is changed so that the volume ratio of the metal dopant in the region adjacent to the capping layer in the second electrode and in the region adjacent to the light emitting structure is less than the average volume ratio. In an embodiment having the metal dopant doping concentration profile of FIG. 9A, the second electrode may have a transmittance greater than or equal to about 70% at about 550 nm. Accordingly, the second electrode may be used as a transmissive electrode or a transflective electrode.

In an embodiment, the ratio of the metal dopant DMT in the region adjacent to the capping layer CPL and the ratio of the metal dopant DMT in the region adjacent to the electron injection layer EIL may be smaller than the ratio of the metal dopant DMT in other regions of the second electrode EL2-a, and accordingly, diffusion of the metal dopant DMT having a smaller work function and a relatively smaller atomic diameter than the metal host HSM into adjacent layers or interfaces with adjacent layers may be minimized.

Accordingly, degradation in interface properties between the capping layer CPL and the second electrode EL2-a and degradation in interface properties between the electron injection layer EIL and the second electrode EL2-a due to a movement of the metal dopant DMT, which are caused upon prolonged exposure to ultraviolet rays (UV) or prolonged use in an external environment, may be improved. In an embodiment, the volume ratio of the metal dopant DMT in the region adjacent to the capping layer CPL and the region adjacent to the electron injection layer EIL may be less than the average volume ratio of the metal dopant DMT in the second electrode EL2-a, and accordingly, damage to interface due to movement of the metal dopant DMT to the interface and subsequent exciton quenching may be minimized to prevent reduction in optical efficiency and element service life. In an embodiment, the metal dopant DMT may be included at a relatively low volume ratio in the region adjacent to the capping layer CPL or the electron injection layer EIL, thereby minimizing the movement of metal dopants DMT to the interface with adjacent layers, and accordingly, roughness of the interface may remain uniform to prevent diffuse reflection, and the like, resulting in excellent optical properties and light efficiency characteristics. For example, the second electrode EL2-a according to an embodiment may have excellent transmittance characteristics and excellent reliability characteristics even upon prolonged use or exposed to external environments such as ultraviolet rays.

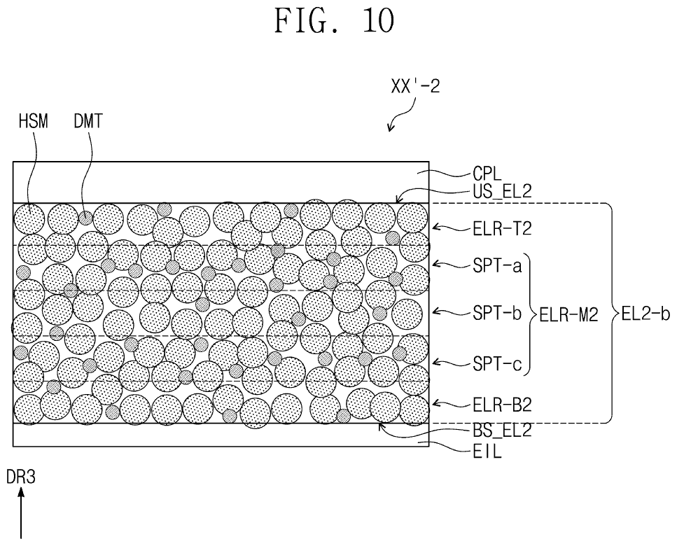

FIG. 10 is a schematic cross-sectional view enlarging a portion of a light emitting element according to an embodiment. Region XX′-2 in FIG. 10 may correspond to region XX′ in FIG. 5.

Referring to FIG. 10, in the light emitting element of an embodiment, a second electrode EL2-b may include a first region ELR-T2 including a first surface US_EL2 in contact with the capping layer CPL, a second region ELR-B2 including a second surface BS_EL2 in contact with the light emitting structure EU (FIG. 5), and a third region ELR-M2 disposed between the first region ELR-T2 and the second region ELR-B2. In an embodiment, the average volume ratio of the metal dopant DMT in the third region ELR-M2 may be greater than each of the volume ratio of the metal dopant DMT in the first region ELR-T2 and the volume ratio of the metal dopant DMT in the second region ELR-B2.

The volume ratio of the metal dopant DMT in the first region ELR-T2 and the volume ratio of the metal dopant DMT in the second region ELR-B2 may each be less than the average volume ratio of the metal dopant DMT throughout the second electrode EL2-b.

In an embodiment, the third region ELR-M2 may include at least one sub-region in which the volume ratio of the metal dopant DMT is less than the average volume ratio of the metal dopant DMT throughout the second electrode EL2-b.

In an embodiment shown in FIG. 10, the third region ELR-M2 may include a first sub-region SPT-b in which the volume ratio of the metal dopant DMT is less than the average volume ratio of the metal dopant DMT throughout the second electrode EL2-b, a second sub-region SPT-a disposed between the first region ELR-T2 and the first sub-region SPT-b and in which the volume ratio of the metal dopant DMT is greater than the average volume ratio of the metal dopant DMT throughout the second electrode EL2-b, and a third sub-region SPT-c disposed between the second region ELR-B2 and the first sub-region SPT-b and in which the volume ratio of the metal dopant DMT is greater than the average volume ratio of the metal dopant DMT throughout the second electrode EL2-b.

The metal dopant DMT may be distributed throughout the first region ELR-T2, the second region ELR-B2, and the third region ELR-M2. The volume ratio of the metal dopant in the first region ELR-T2 and the second region ELR-B2 may be less than the average volume ratio of the metal dopant DMT in the second electrode EL2-b. In an embodiment, the volume ratio of the metal dopant in the first sub-region SPT-b of the third region ELR-M2 may be less than the average volume ratio of the metal dopant DMT in the second electrode EL2-b. In an embodiment, the volume ratio of the metal dopant in the second sub-region SPT-a and the third sub-region SPT-c of the third region ELR-M2 may be greater than the average volume ratio of the metal dopant DMT in the second electrode EL2-b.

The second electrode EL2-b may be formed by co-deposition of the metal host HSM and the metal dopant DMT using thermal evaporation. The ratio of deposition rates of the metal host HSM and the metal dopant DMT may vary in the second region ELR-B2, the third region ELR-M2, and the first region ELR-T2 of the second electrode EL2-b according to an embodiment shown in FIG. 10.

When forming the second electrode EL2-b included in the light emitting element of an embodiment, the deposition rate of the metal dopant DMT may be relatively low in the first region ELR-T2, the second region ELR-B2, and the first sub-region SPT-b, and relatively high in the second sub-region SPT-a and the third sub-region SPT-c.

Accordingly, the concentration (volume ratio) of the metal dopant DMT in the second sub-region SPT-a and the third sub-region SPT-c of the second electrode may be greater than the concentration (volume ratio) of the metal dopant DMT in each of the first region ELR-T2, the second region ELR-B2, and the first sub-region SPT-b of the second electrode.

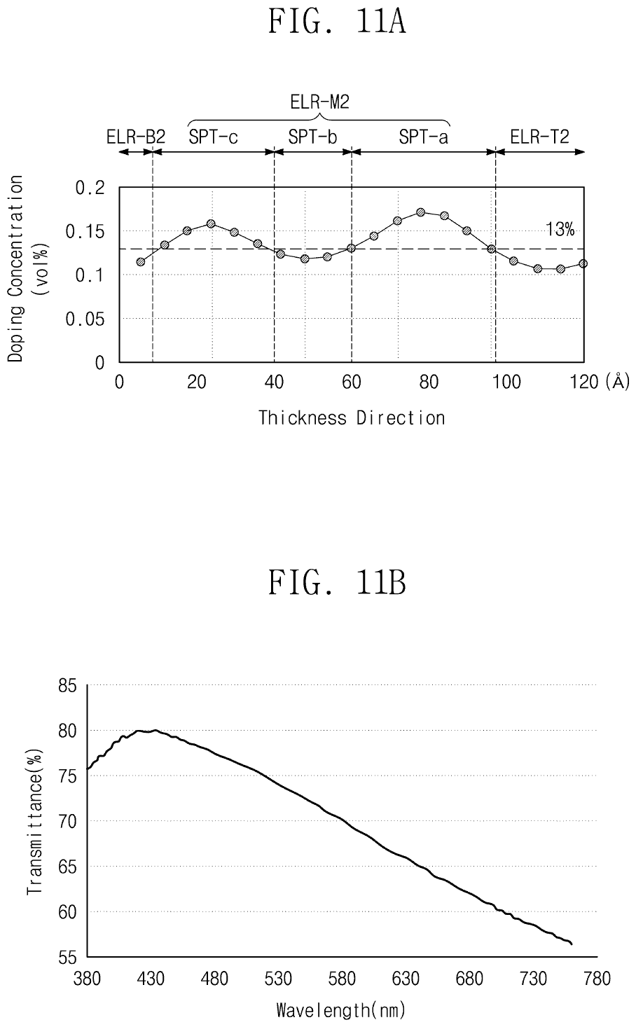

FIG. 11A is a graph showing a doping concentration profile along the thickness direction of the second electrode in a light emitting element having the structure of an embodiment shown in FIG. 10. FIG. 11B is a graph showing the transmittance characteristics of Example having the doping concentration profile shown in FIG. 11A.

Referring to FIG. 11A, the doping concentration of the metal dopant along the thickness direction in the second electrode in an embodiment may have a profile including at least one concave region in the third region ELR-M2. Accordingly, the third region ELR-M2 may include at least one point at which the volume ratio of the metal dopant is maximum on both sides of the center of the second electrode EL2-b. For example, a portion having a relatively high ratio of the metal host HSM in the second electrode EL2-b may not be concentrated in the center of the third region ELR-M2 but may be positioned dispersedly with a concentration profile. Accordingly, the phenomenon that the metal host HSM is excessively concentrated and aggregated in one portion may be further improved.

In an embodiment, the third region ELR-M2 may include at least one sub-region SPT-b having a doping concentration of metal dopant below the average doping concentration and sub-regions SPT-a and SPT-c each having a doping concentration of metal dopant greater than the average doping concentration on both sides of the at least one sub-region SPT-b.

In an embodiment of FIG. 11A, the average doping concentration of the metal dopant in the second electrode may be about 13%, and the second region ELR-B2 and the first region ELR-T2 may have a doping concentration lower than the average doping concentration of 13%. In an embodiment, the first sub-region SPT-b may have a doping concentration lower than the average doping concentration of 13%. In an embodiment, the third region ELR-M2 may have a doping concentration higher than the average doping concentration of 13%, and the second sub-region SPT-a and the third sub-region SPT-c disposed on both sides of the first sub-region SPT-b may each have a doping concentration higher than the average doping concentration of 13%.

The second electrode EL2-b (FIG. 10) having the doping concentration profile shown in FIG. 11A may have a deposition rate of the metal dopant DMT less than or equal to about 0.13 (Å/sec) in the second region ELR-B1, a deposition rate of the metal dopant DMT greater than or equal to about 0.13 (Å/sec) in the third sub-region SPT-c, a deposition rate of the metal dopant DMT less than or equal to about 0.13 (Å/sec) in the first sub-region SPT-b, a deposition rate of the metal dopant DMT greater than or equal to about 0.13 (Å/sec) in the second sub-region SPT-a, and a deposition rate of the metal dopant DMT less than or equal to about 0.13 (Å/sec) in the first region ELR-T2.

FIG. 11B shows transmittance characteristics of the embodiment in which the deposition rate of the metal dopant is changed so that the volume ratio of the metal dopant in the region adjacent to the capping layer in the second electrode and in the region adjacent to the light emitting structure is less than the average volume ratio. In an embodiment having the metal dopant doping concentration profile of FIG. 11A, the second electrode may have a transmittance greater than or equal to about 70% at about 550 nm. Accordingly, the second electrode may be used as a transmissive electrode or a transflective electrode.

In an embodiment, the ratio of the metal dopant DMT in the region adjacent to the capping layer CPL and the ratio of the metal dopant DMT in the region adjacent to the electron injection layer EIL may be smaller than the average metal dopant ratio of the second electrode EL2-b, and accordingly, diffusion of the metal dopant DMT having a smaller work function and a relatively smaller atomic diameter than the metal host HSM into adjacent layers or interfaces with adjacent layers may be minimized.

Accordingly, degradation in interface properties between the capping layer CPL and the second electrode EL2-b and degradation in interface properties between the electron injection layer EIL and the second electrode EL2-b due to movement of the metal dopant DMT, which are caused upon prolonged exposure to ultraviolet rays (UV) or prolonged use in an external environment, may be improved. In an embodiment, the volume ratio of the metal dopant DMT in the region adjacent to the capping layer CPL and the region adjacent to the electron injection layer EIL may be less than the average volume ratio of the metal dopant DMT in the second electrode EL2-b, and accordingly, damage to interface due to movement of the metal dopant DMT to the interface and subsequent exciton quenching may be minimized to prevent reduction in optical efficiency and element service life. In an embodiment, the metal dopant DMT may be included at a relatively low volume ratio in the region adjacent to the capping layer CPL or the electron injection layer EIL, thereby minimizing the movement of metal dopants DMT to the interface with adjacent layers, and accordingly, roughness of the interface may remain uniform to prevent diffuse reflection, and the like, resulting in excellent optical properties and light efficiency characteristics. For example, the second electrode EL2-b according to an embodiment may have excellent transmittance characteristics and excellent reliability characteristics even upon prolonged use or exposed to external environments such as ultraviolet rays.

The light emitting element of an embodiment having the structure of the second electrode according to an embodiment described with reference to FIGS. 8 to 11B may be included in the display device of an embodiment described with reference to FIGS. 1 to 4. Accordingly, the display device of an embodiment including the light emitting element of an embodiment may have excellent display quality and improved reliability by regulating the doping concentration of the metal dopant in the second electrode according to the thickness position and varying the volume ratio of the metal dopant.

In the light emitting element of an embodiment, a metal dopant may be included in addition to the metal host in the second electrode disposed below the capping layer, and accordingly, the aggregation phenomenon of the metal host may be improved. In an embodiment, the volume ratio of the metal dopant may be relatively low in the region adjacent to the capping layer to improve interface characteristics between the capping layer and the second electrode, thereby showing excellent element characteristics and improved reliability characteristics.

In an embodiment, the display device of an embodiment may include a light emitting element in a display element layer, and an electrode in which the volume ratio of a metal dopant is relatively low in the region adjacent to the capping layer in the light emitting element, and may thus have improved reliability and maintain excellent display quality as well.

A light emitting element of an embodiment may both maintain excellent element performance and optical properties and have improved reliability by making a concentration of a metal dopant in a region adjacent to an upper surface lower than an average concentration of a metal dopant in a layer.

A display device of an embodiment may include a light emitting element having an optimized ratio of a dopant in an electrode, and may thus have excellent display quality and improved reliability.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light emitting element comprising:
a first electrode;
a light emitting structure disposed on the first electrode and including an emission layer;
a second electrode disposed on the light emitting structure and including silver (Ag) and a metal dopant; and
a capping layer directly disposed on the second electrode, wherein
an average volume ratio of the metal dopant in the second electrode is less than or equal to about 30%, and
a volume ratio of the metal dopant in a region adjacent to the capping layer is less than the average volume ratio of the metal dopant in the second electrode.

2. The light emitting element of claim 1, wherein the metal dopant comprises at least one of Al, Au, Cu, Mg, Ti, In, Ni, C, Pd, F, Na, Si, Ca, Mn, Fe, Co, Zn, Ga, Ge, Mo, Sn, In, Pt, Pb, Fe, Yb, Lu, or Pa.

3. The light emitting element of claim 1, wherein
the metal dopant is Mg, and
the average volume ratio of the metal dopant in the second electrode is in a range of about 3% to about 10%.

4. The light emitting element of claim 1, wherein the volume ratio of the metal dopant in the second electrode gradually decreases in a direction from the light emitting structure to the capping layer.

5. The light emitting element of claim 1, wherein the second electrode has a thickness in a range of about 50 Å to about 300 Å.

6. The light emitting element of claim 1, wherein the second electrode is formed by co-deposition of the silver and the metal dopant using a method of thermal evaporation.

7. The light emitting element of claim 1, wherein
the second electrode comprises a first region including a first surface contacting the capping layer, a second region including a second surface contacting the light emitting structure, and a third region disposed between the first region and the second region, and
a first volume ratio of the metal dopant in the first region and a second volume ratio of the metal dopant in the second region are each less than the average volume ratio of the metal dopant in the second electrode.

8. The light emitting element of claim 7, wherein a third volume ratio of the metal dopant in the third region is greater than the average volume ratio of the metal dopant in the second electrode.

9. The light emitting element of claim 7, wherein the third region comprises:
a first sub-region having a third volume ratio of the metal dopant less than the average volume ratio of the metal dopant in the second electrode;
a second sub-region disposed between the first region and the first sub-region and having a fourth volume ratio of the metal dopant greater than the average volume ratio of the metal dopant in the second electrode; and
a third sub-region disposed between the second region and the first sub-region and having a fifth volume ratio of the metal dopant greater than the average volume ratio of the metal dopant in the second electrode.

10. The light emitting element of claim 7, wherein the third region comprises at least one sub-region having a third volume ratio of the metal dopant less than the average volume ratio of the metal dopant in the second electrode.

11. The light emitting element of claim 1, wherein
the first electrode is a reflective electrode, and
the second electrode is a transmissive electrode or a transflective electrode.

12. The light emitting element of claim 1, wherein the second electrode has a transmittance greater than or equal to about 70% at about 550 nm.

13. The light emitting element of claim 1, wherein
the light emitting structure comprises the emission layer, a hole transport region disposed between the first electrode and the emission layer, and an electron transport region disposed between the emission layer and the second electrode, and
the electron transport region is directly disposed below the second electrode and comprises an electron injection layer including Yb.

14. A display device comprising:
a circuit layer; and
a display element layer disposed on the circuit layer and including a light emitting element and a pixel defining layer including a pixel opening; wherein
the light emitting element includes:
a first electrode;
a light emitting structure disposed on the first electrode and including an emission layer;
a second electrode disposed on the light emitting structure and including silver (Ag) and a metal dopant; and
a capping layer directly disposed on the second electrode,
an average volume ratio of the metal dopant in the second electrode is less than or equal to about 30%, and
a volume ratio of the metal dopant in a region adjacent to the capping layer is less than the average volume ratio of the metal dopant in the second electrode.

15. The display device of claim 14, wherein the metal dopant comprises at least one of Al, Au, Cu, Mg, Ti, In, Ni, C, Pd, F, Na, Si, Ca, Mn, Fe, Co, Zn, Ga, Ge, Mo, Sn, In, Pt, Pb, Fe, Yb, Lu, or Pa.

16. The display device of claim 14, wherein
the second electrode comprises a first region including a first surface contacting the capping layer, a second region including a second surface contacting the light emitting structure, and a third region disposed between the first region and the second region, and
a first volume ratio of the metal dopant in the first region and a second volume ratio of the metal dopant in the second region are each less than the average volume ratio of the metal dopant in the second electrode.

17. The display device of claim 16, wherein a third volume ratio of the metal dopant in the third region is greater than the average volume ratio of the metal dopant in the second electrode.

18. The display device of claim 16, wherein the third region comprises:
a first sub-region having a third volume ratio of the metal dopant less than the average volume ratio of the metal dopant in the second electrode;
a second sub-region disposed between the first region and the first sub-region and having a fourth volume ratio of the metal dopant greater than the average volume ratio of the metal dopant in the second electrode; and
a third sub-region disposed between the second region and the first sub-region and having a fifth volume ratio of the metal dopant greater than the average volume ratio of the metal dopant in the second electrode.

19. The display device of claim 14, wherein
the metal dopant is Mg, and
the second electrode is formed by co-deposition of the silver and the Mg using a method of thermal evaporation.

20. The display device of claim 14, wherein
the light emitting structure comprises the emission layer, a hole transport region disposed between the first electrode and the emission layer, and an electron transport region disposed between the emission layer and the second electrode, and
the electron transport region is directly disposed below the second electrode and comprises an electron injection layer including Yb.
